(19) United States
(12) Patent Application Publication
(10) Pub. No.: US 2025/0331369 A1
(43) Pub. Date: Oct. 23, 2025

(54) DISPLAY PANEL, MANUFACTURING METHOD THEREOF, AND DISPLAY DEVICE

(71) Applicant: HKC CORPORATION LIMITED, Shenzhen (CN)

(72) Inventors: Hongcheng Li, Shenzhen (CN); Linlin Qiu, Shenzhen (CN); Lei Jiang, Shenzhen (CN); Guangsheng Li, Shenzhen (CN); Haijiang Yuan, Shenzhen (CN)

(21) Appl. No.: 19/180,133

(22) Filed: Apr. 16, 2025

(30) Foreign Application Priority Data
Apr. 17, 2024 (CN) 202410465334.X

(51) Int. Cl. H10K 59/122; H10K 59/12; H10K 59/80; H10K 71/60; H10K 77/10; H10K 102/00

(52) U.S. Cl. CPC H10K 59/122; H10K 59/1201; H10K 59/873; H10K 71/60; H10K 77/111; H10K 2102/311

(57) ABSTRACT

A display panel, a manufacturing method thereof, and a display device are disclosed. The display panel further includes a substrate, a pixel driving layer, a pixel defining layer, a light-emitting element layer, a metal barrier layer, an inorganic barrier layer, and an encapsulation layer. The pixel defining layer is arranged on the pixel driving layer and extends from a display area to a transition area. The light-emitting element layer includes multiple light-emitting elements, which are arranged in the openings respectively. A transition light-emitting layer is arranged in the transition area. The metal barrier layer is arranged in the transition area and arranged on the pixel defining layer. The inorganic barrier layer is arranged on the metal barrier layer. The encapsulation layer is arranged on the light-emitting elements, the pixel defining layer, and the inorganic barrier layer.

### CROSS-REFERENCE TO RELATED APPLICATIONS

This application claims the priority and benefit of Chinese patent application number 202410465334X, titled “Display Panel, Manufacturing Method Thereof, and Display Device” and filed Apr. 17, 2024 with China National Intellectual Property Administration, the entire contents of which are incorporated herein by reference.

### TECHNICAL FIELD

This application relates to the field of display technology, and more particularly relates to a display panel, a manufacturing method thereof, and a display device.

### BACKGROUND

The description provided in this section is intended for the mere purpose of providing background information related to the present application but does not necessarily constitute prior art.

Organic light emitting diodes (OLEDs) have the advantages of surface light source, cold light, energy saving, fast response, flexibility, ultra-thinness, and low cost. Furthermore, their mass production technology is becoming increasingly mature. Since OLED has poor stability and is extremely sensitive to water and oxygen, the encapsulation technology is particularly critical. The purpose of encapsulation is mainly to prevent water vapor and oxygen from entering the OLED. Then cracks are easily generated during the manufacturing process of the encapsulation layer. When cracks appear on the display screen or water vapor enters from the outside, the aging speed of the devices of the OLED organic light-emitting layer will be accelerated. Therefore, strict encapsulation may need to be performed to extend the life and improve stability. With the rapid development of display devices, users have higher and higher requirements for the screen-to-body ratio of display panels. Take mobile phones as an example. Functional components such as cameras, sensors, or earpieces need to be arranged on the display panel. These components will affect the screen-to-body ratio of the display panel.

In order to achieve a full-screen display, a hole may be dug in the display area of the display panel to form a light-transmitting area, and a camera and other functional components are arranged below the light-transmitting area. The related hole-digging method mainly uses laser cutting to make holes. In actual applications, it may cause the edge of the hole to burn and carbonize, thereby affecting the display effect of the display panel.

### SUMMARY

It is therefore one purpose of this application to provide a display panel and a manufacturing method thereof and a display device, which prevent laser cutting from affecting the film layers by setting a metal barrier layer in the transition area, thereby improving the quality of the display panel.

This application discloses a display panel. The display panel includes a light-transmitting area, a transition area, and a display area. The transition area is disposed around the light-transmitting area. The display area is disposed around the transition area. The display panel further includes a substrate, a pixel driving layer, a pixel defining layer, a light-emitting element layer, a metal barrier layer, an inorganic barrier layer, and an encapsulation layer. The pixel driving layer is arranged on the substrate. The pixel defining layer is arranged on the pixel driving layer and extends from the display area to the transition area. In the display area, the pixel defining layer defines a plurality of openings. The light-emitting element layer includes a plurality of light-emitting elements, and the plurality of light-emitting elements are respectively arranged in the openings. A transition light-emitting layer is arranged in the transition area. The metal barrier layer is arranged in the transition area and arranged on the pixel defining layer. The inorganic barrier layer is arranged on the metal barrier layer. The encapsulation layer is arranged on the light-emitting elements, the pixel defining layer, and the inorganic barrier layer.

In some embodiments, the metal barrier layer further includes a metal barrier extension. At a position where the transition area is adjacent to the light-transmitting area, the metal barrier extension is used to cover the sides of the pixel driving layer and the pixel defining layer.

In some embodiments, the inorganic barrier layer further includes an inorganic barrier extension, and the inorganic extension covers the metal barrier extension. The encapsulation layer further covers the inorganic barrier extension.

In some embodiments, on the orthographic projection on the substrate, the projection of the metal barrier layer lies within the projection range of the inorganic barrier layer. The width of the inorganic barrier layer is greater than the width of the metal barrier layer. The transition light-emitting layer includes a first light-emitting layer and a second light-emitting layer. The inorganic barrier layer forms a partition between the first light-emitting layer and the second light-emitting layer. The first light-emitting layer is arranged on the pixel defining layer. The second light-emitting layer is arranged on the inorganic barrier layer and extends to the inorganic barrier extension.

In some embodiments, the inorganic barrier layer is wider than the metal barrier layer on the side facing away from the light-transmitting area. On the orthographic projection on the substrate, the first light-emitting layer partially overlaps the second light-emitting layer.

In some embodiments, the substrate is a flexible substrate, and the flexible substrate includes a first organic layer, a barrier layer, and a second organic layer. The first organic layer and the barrier layer each extend from the transition area to the light-transmitting area. The second organic layer is arranged in the transition area.

In some embodiments, the metal barrier layer is formed of one or more materials selected from copper, molybdenum, aluminum, or titanium. The inorganic barrier layer is formed of one or more materials selected from silicon oxynitride, silicon nitride, or silicon oxide.

In some embodiments, the thickness of the metal barrier layer lies between 0.8 μm and 1.5 μm, and the thickness of the inorganic barrier layer lies between 0.3 μm and 0.8 μm.

This application further discloses a method for manufacturing a display panel, the method including:
providing a substrate;
forming a pixel driving layer on the substrate;
forming a pixel defining layer on the pixel driving layer, the pixel defining layer extending from the display area to the transition area, and the pixel defining layer defining a plurality of openings in the display area;
forming a metal barrier layer on the pixel defining layer, the metal barrier layer being arranged in the transition area;
forming an inorganic barrier layer on the metal barrier layer; and
forming a light-emitting element layer, where a plurality of light-emitting elements are respectively formed in the plurality of openings, and a transition light-emitting layer is formed in the transition area;
forming an encapsulation layer, the encapsulation layer being arranged on the plurality of light-emitting elements, the pixel defining layer, and the inorganic barrier layer.

This application further discloses a display device, including a driving circuit and the above-mentioned display panel, where the driving circuit is used to drive the display panel to display.

In this application, a metal barrier layer and an inorganic barrier layer are arranged in the transition area. The metal barrier layer has a reflective effect on the laser, thereby preventing part of the laser from passing through the light-transmitting area and entering the transition area during the laser cutting and drilling process thereby sintering and destroying the film layers in the transition area. By reflecting the laser, the film layers below the transition area are protected. Furthermore, the metal barrier layer also has a heat-insulating effect and can block the heat generated during the laser cutting process. The inorganic barrier layer is further disposed on the metal barrier layer, and the inorganic barrier layer is used to prevent the debris produced from laser cutting from entering the metal barrier layer, thereby protecting the metal barrier layer. Furthermore, the inorganic barrier layer is used to cover the metal barrier layer to prevent the metal barrier layer from being corroded when water vapor invades after cutting. Compared with the solution of arranging a retaining wall in the transition area, the retaining wall may be formed of organic materials, which cannot block the laser during the laser cutting process. This application utilizes the combination of the metal barrier layer and the inorganic barrier layer to prevent the problem of burning and carbonization at the edge of the opening caused by laser cutting, so as to improve the display quality of the display panel.

### BRIEF DESCRIPTION OF DRAWINGS

The accompanying drawings are used to provide a further understanding of the embodiments according to this application, and constitute a part of the specification. They are used to illustrate the embodiments according to this application, and explain the principles of this application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a top view schematic diagram of a display panel of a first embodiment of this application.

FIG. 2 is a cross-sectional schematic diagram of the display panel of the first embodiment of this application.

FIG. 3 is a schematic diagram of a display panel of a second embodiment of this application.

FIG. 4 is a schematic diagram of a display panel of a third embodiment of this application.

FIG. 5 is a flowchart of a method for manufacturing a display panel according to this application.

FIG. 6 is a schematic flow chart of a manufacturing process of a display panel according to this application.

FIG. 7 is a schematic diagram of a display device according to this application.

In the drawings: 100, display panel; 101, display area; 102, light-transmitting area; 103, transition area; 110, substrate; 111, first organic layer; 112, barrier layer; 113, second organic layer; 120, pixel driving layer; 130, pixel defining layer; 150, metal barrier layer; 151, metal barrier extension; 160, inorganic barrier layer; 161, inorganic barrier extension; 170, encapsulation layer; 180, transition light-emitting layer; 181, first light-emitting layer; 182, second light-emitting layer; 200, display device; 210, driving circuit.

### DETAILED DESCRIPTION OF EMBODIMENTS

It should be understood that the terms used herein, the specific structures and functional details disclosed therein are merely representative for describing some specific embodiments, but this application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in this application can be understood depending on specific contexts.

This application will be described in detail below with reference to the accompanying drawings and some optional embodiments.

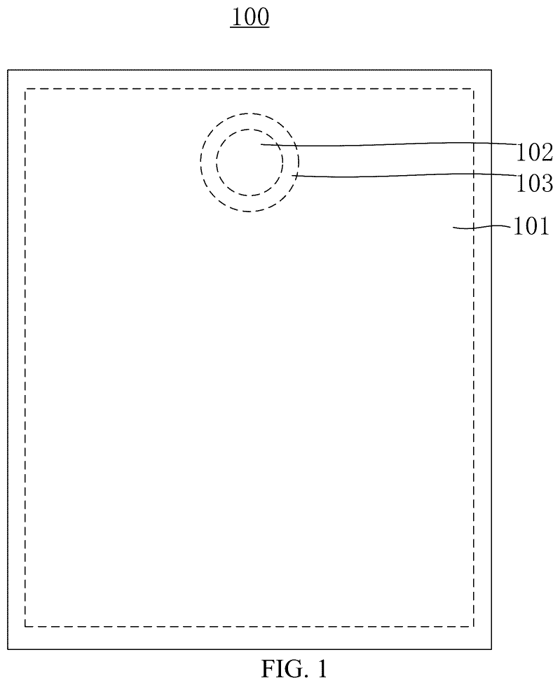

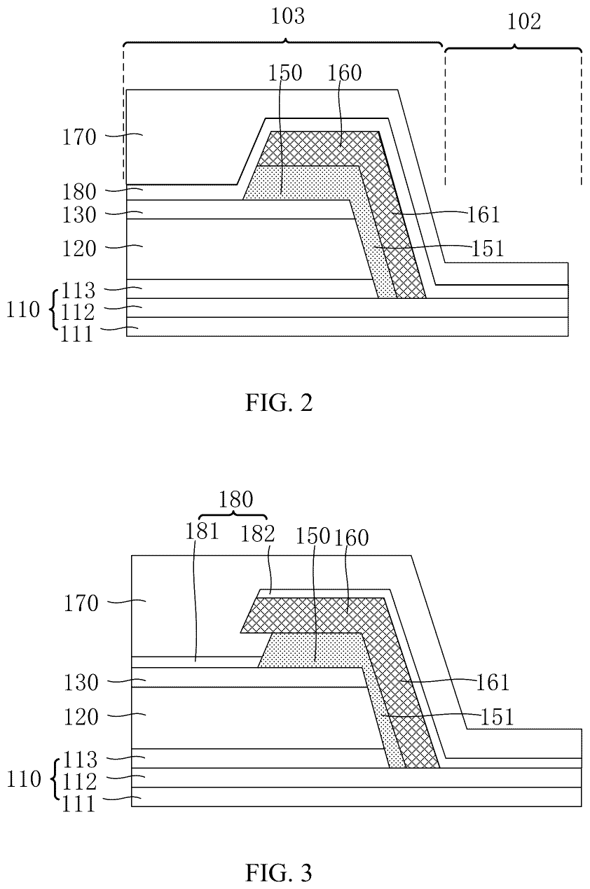

FIG. 1 is a schematic top view of a display panel of a first embodiment of this application. FIG. 2 is a schematic cross-sectional view of a display panel of the first embodiment of this application. As shown in FIGS. 1 to 2, this application discloses a display panel 100. The display panel 100 includes a light-transmitting area 102, a transition area 103, and a display area 101. The transition area 103 is arranged around the light-transmitting area 102, and the display area 101 is arranged around the transition area 103. The light-transmitting area 102 is a hole-punching area of the display panel 100. The hole-punching removes the film layers of the display panel 100 in the hole-punching area. The light-transmitting area 102 may be disposed in the display area 101. The display area 101 and the light-transmitting area 102 are connected through the transition area 103. A partial structure is arranged in the transition area 103 to prevent the display panel 100 from being invaded by water vapor or oxygen in the light-transmitting area 102.

The display panel 100 further includes a substrate 110, a pixel driving layer 120, a pixel defining layer 130, a light-emitting element layer, a metal barrier layer 150, an inorganic barrier layer 160, and an encapsulation layer 170. The pixel driving layer 120 is disposed on the substrate 110. The pixel defining layer 130 is disposed on the pixel driving layer 120 and extends from the display area 101 to the transition area 103. In the display area 101, the pixel defining layer 130 is further defined with a plurality of openings. The light-emitting element layer includes a plurality of light-emitting elements. The plurality of light-emitting elements are respectively disposed in the openings. A transition light-emitting layer 180 is disposed in the transition area 103. The metal barrier layer 150 is disposed in the transition area 103 and on the pixel defining layer 130. The inorganic barrier layer 160 is arranged on the metal barrier layer 150. The encapsulation layer 170 is arranged on the light-emitting element, the pixel defining layer 130, and the inorganic barrier layer 160.

In this application, a metal barrier layer 150 and an inorganic barrier layer 160 are arranged in the transition area 103. The metal barrier layer 150 has a reflective effect on the laser, thereby preventing part of the laser from passing through the light-transmitting area 102 and entering the transition area 103 during the laser cutting and drilling process thus sintering and destroying the film layers in the transition area 103. By reflecting the laser, the film layers below the transition area 103 are protected. Furthermore, the metal barrier layer 150 also has a heat-insulating effect and can block the heat generated during the laser cutting process. The inorganic barrier layer 160 is further disposed on the metal barrier layer 150. The inorganic barrier layer 160 is used to prevent the debris produced in laser cutting from entering the metal barrier layer 150, thereby protecting the metal barrier layer 150. Furthermore, the inorganic barrier layer 160 is used to cover the metal barrier layer 150 to prevent the metal barrier layer 150 from being corroded by water vapor after cutting. Compared with the solution of arranging a retaining wall in the transition area 103, the retaining wall may be formed of organic materials, which cannot block the laser during the laser cutting process. This application utilizes the combination of the metal barrier layer 150 and the inorganic barrier layer 160 to prevent the problem of burning and carbonization at the edge of the opening caused by laser cutting, so as to improve the display quality of the display panel 100.

In particular, the substrate 110 in this embodiment is a flexible substrate. The flexible substrate includes a first organic layer 111, a barrier layer 112, and a second organic layer 113. The first organic layer 111 and the barrier layer 112 extend from the transition area 103 to the light-transmitting area 102. The second organic layer 113 is arranged in the transition area 103. A barrier layer 112 is disposed between the first organic layer 111 and the second organic layer 113, and the barrier layer 112 has the function of blocking water and oxygen.

The first organic layer 111 and the second organic layer 113 may be formed of PI film (Polyimide Film) materials. The barrier layer 112 may be formed of inorganic materials, etc. In the process of laser cutting, the flexible substrate in the light-transmitting area 102 in this embodiment also needs to be opened. The characteristics of the PI film determine that it is easy to be carbonized by laser sintering. In addition to the PI film between the light-transmitting area 102 and the transition area 103, the PI film in the transition area 103 may also be carbonized. In particular, in the absence of a metal barrier layer 150, when the laser penetrates the multiple transparent film layers of the transition area 103 and enters the second organic layer 113 or the first organic layer 111, the second organic layer 113 or the first organic layer 111 in the transition area 103 may still be carbonized, thereby affecting the quality of the flexible substrate. In this solution, the laser can be better controlled within the light-transmitting area 102 by setting the metal barrier layer 150, so as to protect the first organic layer 111 and the second organic layer 113. Of course, in actual use, laser cutting equipment with a relatively lower precision may be used to reduce costs as much as possible without affecting the quality of the display panel 100.

In particular, the pixel driving layer 120 may include multiple metal layers and multiple insulating layers, and the multiple metal layers and insulating layers are used to form thin film transistors, signal transmission lines, etc. that drive the light-emitting elements to emit light. The thin film transistors are arranged in an array, and the pixel driving layer 120 may also be called an array layer.

Furthermore, the metal barrier layer 150 further includes a metal barrier extension 151. At the position of the transition area 103 adjacent to the light-transmitting area 102, the metal barrier extension 151 is used to cover the sides of the pixel driving layer 120 and the pixel defining layer 130. Since the film layers have a certain thickness, at the edge position from transition area 103 to light-transmitting area 102, the metal barrier extension 151 is disposed to wrap around the edge position to prevent the laser from penetrating and damaging the PI film at the side position.

In particular, the bottom of the metal barrier extension 151 is in direct contact with the barrier layer 112. The metal barrier extension 151 also covers the side of the second organic layer 113 to protect the side of the second organic layer 113 from laser damage.

In one embodiment, an inorganic barrier extension 161 is further disposed on the metal barrier extension 151. The inorganic extension covers the metal barrier extension 151. The encapsulation layer 170 also covers the inorganic barrier extension 161. The inorganic barrier extension 161 has the ability to block the intrusion of water and oxygen. On the side of the metal barrier extension 151 facing away from the metal barrier layer 150, the inorganic barrier layer 160 and the inorganic barrier extension 161 are used to block the entry of water and oxygen, thereby protecting the metal barrier layer 150 and the metal barrier extension 151 from being corroded by water and oxygen.

In particular, the light-emitting element layer includes a plurality of light-emitting elements. Each light-emitting element may include a bottom electrode, a light-emitting layer, and a top electrode. The bottom electrode may be formed before the pixel defining layer 130 and is formed at the opening positions. Due to the whole-surface manufacturing process, in addition to the light-emitting layer at the opening position, a transition light-emitting layer 180 is also disposed in the transition area 103, and a light-emitting layer is also disposed in the light-transmitting area 102. Only the light-emitting layer disposed at the opening position is driven by the bottom electrode and the top electrode to emit light, while the light-emitting layer of the transition area 103 and the light-transmitting area 102 does not emit light.

FIG. 3 is a schematic diagram of a display panel of a second embodiment of this application. As shown in FIG. 3 and in further connection with FIGS. 1 to 2, since the light-transmitting area 102 needs to be laser cut, the light-emitting layer will also be cut, so that the transition light-emitting layer 180 is exposed from the cutting position. When water vapor or oxygen invades the opening position, it will cause water vapor or oxygen to enter the light-emitting element along the transition light-emitting layer 180. In this regard, this application further improves the inorganic barrier layer 160 and the metal barrier layer 150 so that the inorganic barrier layer 160 and the metal barrier layer 150 form a partition structure to isolate the transition light-emitting layer 180.

In particular, on the orthographic projection on the substrate 110, the projection of the metal barrier layer 150 lies within the projection range of the inorganic barrier layer 160. The width of the inorganic barrier layer 160 is greater than the width of the metal barrier layer 150. The transition light-emitting layer 180 includes a first light-emitting layer 181 and a second light-emitting layer 182. The inorganic barrier layer 160 forms a partition between the first light-emitting layer 181 and the second light-emitting layer 182. The first light-emitting layer 181 is arranged on the pixel defining layer 130. The second light-emitting layer 182 is arranged on the inorganic barrier layer 160 and extends to the inorganic barrier extension 161.

In this embodiment, the width of the inorganic barrier layer 160 is greater than the width of the metal barrier layer 150. In the process of forming the light-emitting layer, especially the transition light-emitting layer 180 located in the transition area 103, the inorganic barrier layer 160 and the metal barrier layer 150 form an eaves-like structure, so that in the process of evaporating and depositing the light-emitting layer on the entire surface, the transition light-emitting layer 180 is separated into the first light-emitting layer 181 and the second light-emitting layer 182 by the eaves structure in the transition area 103. The first light-emitting layer 181 is disposed on the pixel defining layer 130. The second light-emitting layer 182 is disposed on the inorganic barrier layer 160. Through the action of the inorganic barrier layer 160, the first light-emitting layer 181 and the second light-emitting layer 182 are not connected. Even if water vapor or oxygen invades the second light-emitting layer 182, it will not enter the first light-emitting layer 181 along the second light-emitting layer 182, let alone the light-emitting element in the display area 101.

In particular, the inorganic barrier layer 160 is wider than the metal barrier layer 150 on the side facing away from the light-transmitting area 102. In the transition area 103, the film layer of the side of the inorganic barrier layer 160 facing away from the light-transmitting area 102 exceeds the metal barrier layer 150. In the process of forming the transition light-emitting layer 180, since there is no support of the metal barrier layer 150 under the film layer of the side of the inorganic barrier layer 160 facing away from the light-transmitting area 102, the light-emitting layer cannot be evaporated and deposited, so that the light-emitting layer connected from the inorganic barrier layer 160 to the pixel defining layer 130 cannot be formed. The orthographic projection of the second light-emitting layer 182 on the inorganic barrier layer 160 on the substrate 110 partially overlaps the orthographic projection of the first light-emitting layer 181 on the substrate 110.

In this embodiment, the inorganic barrier layer 160 and the metal barrier layer 150 are arranged in coordination, and the metal barrier layer 150 has a reflective effect on the laser, so that during the laser cutting and drilling process, part of the laser is prevented from passing through the light-transmitting area 102 and entering the transition area 103 thereby sintering and destroying the film layer in the transition area 103. By reflecting the laser, the film layers below the transition area 103 are protected. Furthermore, the metal barrier layer 150 also has a heat-insulating effect and can block the heat generated during the laser cutting process. The inorganic barrier layer 160 is further disposed on the metal barrier layer 150, and the inorganic barrier layer 160 is used to prevent the debris produced from laser cutting from entering the metal barrier layer 150, thereby protecting the metal barrier layer 150. Furthermore, the inorganic barrier layer 160 is used to cover the metal barrier layer 150 to prevent the metal barrier layer 150 from being corroded when water vapor invades after cutting. Furthermore, the width of the inorganic barrier layer 160 is greater than the width of the metal barrier layer 150, so that in the process of forming the transition light-emitting layer 180, the transition light-emitting layer 180 is separated into the first light-emitting layer 181 and the second light-emitting layer 182 by the eaves structure in the transition area 103. The first light-emitting layer 181 is arranged on the pixel defining layer 130, and the second light-emitting layer 182 is arranged on the inorganic barrier layer 160. Through the action of the inorganic barrier layer 160, the first light-emitting layer 181 and the second light-emitting layer 182 are not connected. Even if there is water vapor or oxygen invading the second light-emitting layer 182, it will not enter the first light-emitting layer 181 along the second light-emitting layer 182, let alone enter the light-emitting element in the display area 101.

In particular, the metal barrier layer 150 is formed of one or more materials selected from copper, molybdenum, aluminum, or titanium. The inorganic barrier layer 160 is formed of one or more materials selected from silicon oxynitride, silicon nitride, or silicon oxide. The metal barrier extension 151 is formed in the same manufacturing process as the metal barrier layer 150. The inorganic barrier extension 161 is formed in the same manufacturing process as the inorganic barrier layer 160. The metal barrier layer 150 in this embodiment is formed after the manufacturing process step of the pixel defining layer 130 and before the manufacturing process of the light-emitting element. It may be formed by one or more materials selected from copper, molybdenum, aluminum, or titanium. The metal barrier layer 150 and the metal barrier extension 151 are formed by a vapor deposition process. After the deposition or evaporation of the metal barrier layer 150 and the metal barrier extension 151 is completed, an inorganic barrier layer 160 is formed on the metal barrier layer 150, and an inorganic barrier extension 161 is formed on the metal barrier extension 151. The inorganic barrier layer 160 is patterned by a dry etching process, and the inorganic barrier layer 160 and the inorganic barrier extension 161 in the transition area 103 are retained. The metal barrier layer 150 is patterned by a wet etching process. Due to the lateral corrosion property of the wet etching process, the metal barrier layer 150 at the lower side of the inorganic barrier layer 160 is etched, so that the width of the inorganic barrier layer 160 is greater than the width of the metal barrier layer 150, forming an eaves structure.

The thickness of the metal barrier layer 150 is between 0.8 μm and 1.5 μm, and the thickness of the inorganic barrier layer 160 is between 0.3 μm and 0.8 μm. In this embodiment, since the metal barrier layer 150 needs to block the laser energy, the metal barrier layer 150 needs to have a certain thickness, at least not less than 0.8 μm. The blocking effect of the metal barrier layer 150 on the laser energy remains basically the same after it exceeds 1.5 μm, and the increase of the blocking effect on the laser energy is limited as the thickness increases. Therefore, the thickness of the metal barrier layer 150 is between 0.8 μm and 1.5 μm, and the thickness of the metal barrier extension 151 may also be between 0.8 μm and 1.5 μm. The inorganic barrier layer 160 only needs to have a certain thickness to protect the metal barrier layer 150 and to insulate the metal barrier layer 150 from other film layers. The thickness of the inorganic barrier extension 161 may also be between 0.3 μm and 0.8 μm.

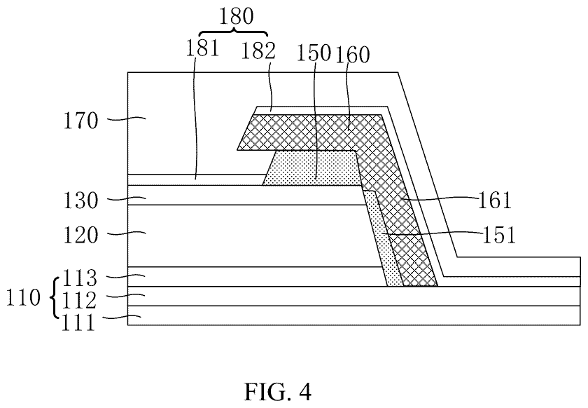

FIG. 4 is a schematic diagram of a display panel of a third embodiment of this application. As shown in FIG. 4, in this embodiment, corrosion occurs between the metal barrier layer 150 and the metal barrier extension 151 after being invaded by water vapor or oxygen, and the corrosion easily extends along the metal. In this regard, in this embodiment, the relationship between the metal barrier layer 150 and the metal barrier extension 151 is improved.

In particular, the metal barrier layer 150 is not connected to the metal barrier extension 151. In this embodiment, the metal barrier layer 150 is separated from the metal extension so that when the metal extension is corroded by water and oxygen, the impact on the metal barrier layer 150 is minimized, and the problem of metal corrosion spreading will not occur.

Under the orthographic projection on the substrate 110, the metal barrier layer 150 and the metal barrier extension 151 may be arranged around the light-transmitting area 102 in the transition area 103. The projection shape of the metal barrier layer 150 and the metal barrier extension 151 is consistent with the punching shape of the light-transmitting area 102. For example, if the punching shape is circular, the metal barrier layer 150 and the metal barrier extension 151 may each be ring-shaped.

In one embodiment, the metal barrier extension 151 may be configured as a plurality of discontinuous metal barrier extension sub-sections arranged around the light-transmitting area 102. The adjacent metal barrier extension sub-sections may be isolated by the inorganic barrier extension 161, and the block-shaped metal barrier extension 151 may be configured to prevent corrosion of a partial area from spreading.

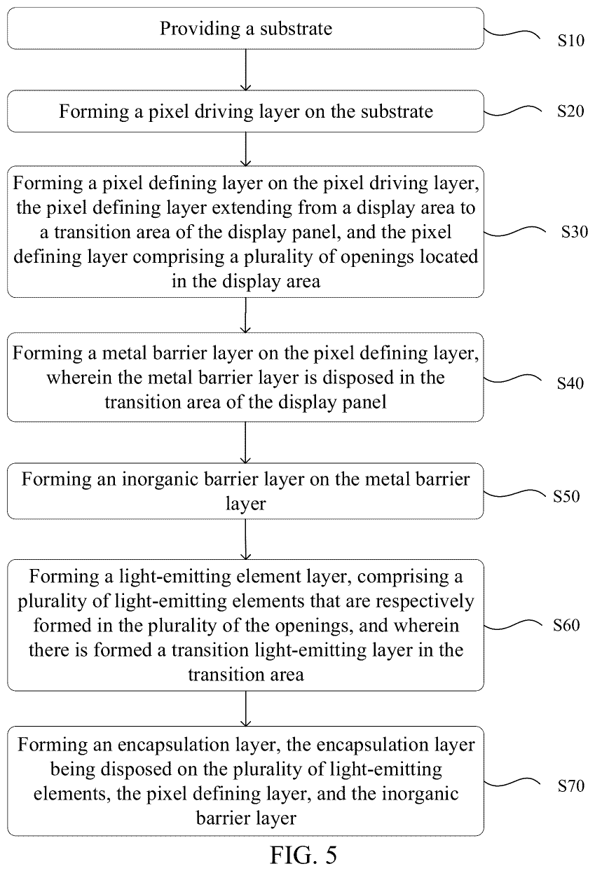

FIG. 5 is a flowchart of a method for manufacturing a display panel of this application. As shown in FIG. 5, this application discloses a method for manufacturing a display panel, the method including:
S10: providing a substrate;
S20: forming a pixel driving layer on the substrate;
S30: forming a pixel defining layer on the pixel driving layer, the pixel defining layer extending from the display area to the transition area, and the pixel defining layer defining a plurality of openings in the display area;
S40: forming a metal barrier layer on the pixel defining layer, the metal barrier layer being arranged in the transition area;
S50: forming an inorganic barrier layer on the metal barrier layer; and
S60: forming a light-emitting element layer, wherein a plurality of light-emitting elements are respectively formed in a plurality of the openings, and a transition light-emitting layer is formed in the transition area;
S70: forming an encapsulation layer, the encapsulation layer being arranged on the light-emitting elements, the pixel defining layer, and the inorganic barrier layer.

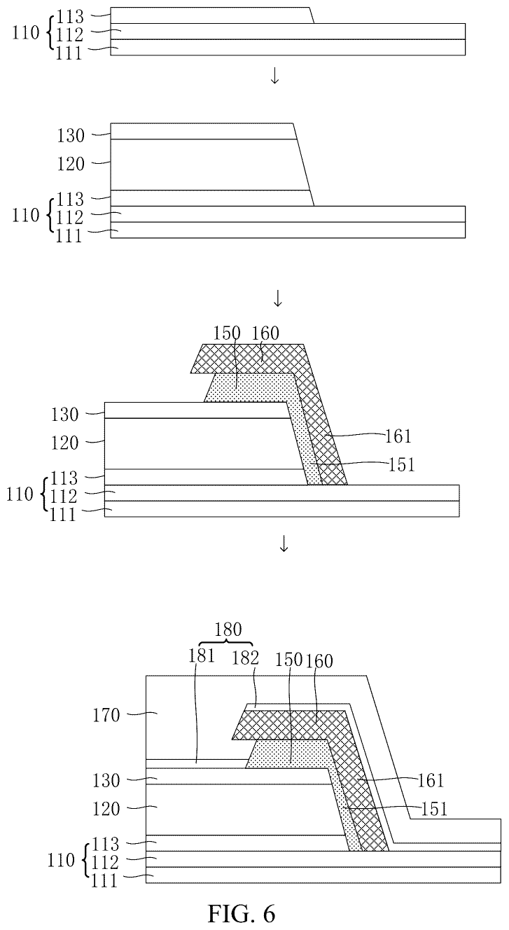

FIG. 6 is a schematic diagram of a manufacturing process of a display panel of this application. As shown in FIG. 6, a flexible substrate is provided, and the flexible substrate includes a first organic layer 111, a barrier layer 112, and a second organic layer 113. A pixel driving layer 120 is formed on the second organic layer 113. A dry etching process may be used to etch the pixel driving layer 120, retaining the pixel driving layer 120 in the display area 101 and the transition area 103, and removing the pixel driving layer 120 in the light-transmitting area 102.

A pixel defining layer 130 is formed on the pixel driving layer 120 and the pixel defining layer 130 is patterned. In the display area 101, a plurality of openings are defined corresponding to the pixel defining layer 130. In the transition area 103, the pixel defining layer 130 covering the sides of the pixel driving layer 120 and the second organic layer 113 is retained. In the light-transmitting area 102, the pixel defining layer 130 is removed. It is worth mentioning that, in the multiple openings in the display area 101, the bottom electrodes of the plurality of light-emitting elements may be formed before the pixel defining layer 130 is formed, and the pixel defining layer 130 is formed after the bottom electrodes are patterned. After forming the pixel defining layer 130, a metal barrier layer 150 is formed in the transition area 103, and an inorganic barrier layer 160 is formed on the metal barrier layer 150.

In the patterning process of the metal barrier layer 150 and the inorganic barrier layer 160, the width of the inorganic barrier layer 160 may be set to be greater than the width of the metal barrier layer 150. For example, the inorganic barrier material is first subjected to a dry etching process to form the inorganic barrier layer 160, and then the metal barrier layer 150 is subjected to a wet etching process. The wet etching process causes the metal material at the lower side of the edge of the inorganic barrier layer 160 to be etched away, so that the width of the inorganic barrier layer 160 is greater than the width of the metal barrier layer 150, hence an eaves structure. Under the effect of the eaves structure, in the subsequent process of forming the light-emitting layer, the first light-emitting layer 181 and the second light-emitting layer 182 that are not connected to each other can be formed in the transition area 103 through the whole-surface forming process. The first light-emitting layer 181 is arranged on the pixel defining layer 130, and the second light-emitting layer 182 is arranged on the inorganic barrier layer 160. Through the action of the inorganic barrier layer 160, the first light-emitting layer 181 and the second light-emitting layer 182 are not connected. Even if water vapor or oxygen invades the second light-emitting layer 182, it will not enter the first light-emitting layer 181 along the second light-emitting layer 182, let alone enter the light-emitting element in the display area 101.

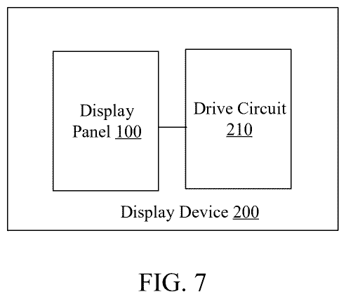

FIG. 7 is a schematic diagram of a display device of this application. As shown in FIG. 7, this application further discloses a display device. The display device 200 includes a driving circuit 210 and any one of the display panels 100 in the above-mentioned embodiments 1, 2, and 3. The driving circuit is used to drive the display panel 100 to display.

It should be noted that the inventive concept of this application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of this application with reference to some specific optional implementations, but it cannot be determined that the specific implementation of this application is limited to these implementations. For those having ordinary skill in the technical field to which this application pertains, several deductions or substitutions may be made without departing from the concept of this application, and all these deductions or substitutions should be regarded as falling within the scope of protection of this application.

What is claimed is:

1. A display panel, comprising a light-transmitting area, a transition area, and a display area; wherein the transition area is disposed around the light-transmitting area, wherein the display area is disposed around the transition area; wherein the display panel comprises:
a substrate;
a pixel driving layer, arranged on the substrate;
a pixel defining layer, arranged on the pixel driving layer and extending from the display area to the transition area, the pixel defining layer further comprising a plurality of openings located in the display area;
a light-emitting element layer, comprising a plurality of light-emitting elements that are respectively arranged in the plurality of openings, and wherein there is further disposed a transition light-emitting layer in the transition area;
a metal barrier layer, arranged in the transition area and on the pixel defining layer;
an inorganic barrier layer, arranged on the metal barrier layer; and
an encapsulation layer, arranged on the plurality of light-emitting elements, the pixel defining layer, and the inorganic barrier layer.

2. The display panel as recited in claim 1, wherein the metal barrier layer further comprises a metal barrier extension;
wherein at a position of the transition area adjacent to the light-transmitting area, the metal barrier extension is configured to cover respective sides of the pixel driving layer and the pixel defining layer.

3. The display panel as recited in claim 2, wherein the inorganic barrier layer further comprises an inorganic barrier extension, which is disposed to cover the metal barrier extension;
wherein the encapsulation layer further covers the inorganic barrier extension.

4. The display panel as recited in claim 1, wherein an orthographic projection of the metal barrier layer on the substrate lies within a range of an orthographic projection of the inorganic barrier layer on the substrate, and wherein the inorganic barrier layer has a width that is greater than a width of the metal barrier layer;
wherein the transition light-emitting layer comprises a first light-emitting layer and a second light-emitting layer; wherein the inorganic barrier layer is configured to separate the first light-emitting layer from the second light-emitting layer;
wherein the first light-emitting layer is arranged on the pixel defining layer, and the second light-emitting layer is arranged on the inorganic barrier layer and extends to the inorganic barrier extension.

5. The display panel as recited in claim 4, wherein a side of the inorganic barrier layer facing away from the light-transmitting area is wider than the metal barrier layer;
wherein an orthographic projection of the first light-emitting layer on the substrate partially overlaps an orthographic projection of the second light-emitting layer on the substrate.

6. The display panel as recited in claim 1, wherein the substrate is a flexible substrate and comprises a first organic layer, a barrier layer, and a second organic layer; wherein the first organic layer and the barrier layer each extend from the transition area to the light-transmitting area;
wherein the second organic layer is disposed in the transition area.

7. The display panel as recited in claim 1, wherein the metal barrier layer is formed of one or more materials selected from the group consisting of copper, molybdenum, aluminum, and titanium; and
wherein the inorganic barrier layer is formed of one or more materials selected from the group consisting of silicon oxynitride, silicon nitride, and silicon oxide.

8. The display panel as recited in claim 1, wherein the metal barrier layer has a thickness that lies in the range of 0.8 μm to 1.5 μm, and wherein the inorganic barrier layer has a thickness that lies in the range of 0.3 μm to 0.8 μm.

9. The display panel as recited in claim 6, wherein the first organic layer and the second organic layer are each formed of a PI film (Polyimide Film) material, and wherein the barrier layer is formed of an inorganic material.

10. The display panel as recited in claim 2, wherein the metal barrier layer is disconnected from the metal barrier extension.

11. The display panel as recited in claim 10, wherein the metal barrier extension comprises a plurality of discontinuous metal barrier extension sub-sections that are arranged around the light-transmitting area; wherein adjacent metal barrier extension sub-sections are separated by the inorganic barrier extension.

12. A method for manufacturing a display panel, comprising:
providing a substrate;
forming a pixel driving layer on the substrate;
forming a pixel defining layer on the pixel driving layer, the pixel defining layer extending from a display area to a transition area of the display panel, and the pixel defining layer comprising a plurality of openings located in the display area;
forming a metal barrier layer on the pixel defining layer, wherein the metal barrier layer is disposed in the transition area of the display panel;
forming an inorganic barrier layer on the metal barrier layer;
forming a light-emitting element layer, comprising a plurality of light-emitting elements that are respectively formed in the plurality of the openings, and wherein there is formed a transition light-emitting layer in the transition area; and
forming an encapsulation layer, the encapsulation layer being disposed on the plurality of light-emitting elements, the pixel defining layer, and the inorganic barrier layer.

13. The method as recited in claim 12, wherein the flexible substrate comprises a first organic layer, a barrier layer, and a second organic layer; wherein the operation of forming the pixel driving layer on the substrate comprises:
forming a pixel driving layer on the second organic layer, etching the pixel driving layer using a dry etching process, retaining the pixel driving layer in the display area and the transition area, and removing the pixel driving layer in the light-transmitting area.

14. The method as recited in claim 12, wherein the operation of forming the inorganic barrier layer on the metal barrier layer comprises:
performing a dry etching process on an inorganic barrier material to form an inorganic barrier layer; and
performing a wet etching process on the metal barrier layer, wherein a metal material at a lower side of an edge of the inorganic barrier layer is also etched away by the wet etching process, thereby forming an eaves structure in which the inorganic barrier layer has a width that is greater than a width of the metal barrier layer;
wherein the operation of forming the light-emitting element layer comprises:
forming the light-emitting element layer by a whole-surface forming process, and forming a first light-emitting layer and a second light-emitting layer that are disconnected from each other in the transition area.

15. A display device, comprising a display panel and a driving circuit configured to drive the display panel to display; wherein the display panel comprises a light-transmitting area, a transition area, and a display area; wherein the transition area is disposed around the light-transmitting area, wherein the display area is disposed around the transition area, wherein the display panel further comprises:
a substrate;
a pixel driving layer, arranged on the substrate;
a pixel defining layer, arranged on the pixel driving layer and extending from the display area to the transition area, the pixel defining layer further comprising a plurality of openings located in the display area;
a light-emitting element layer, comprising a plurality of light-emitting elements that are respectively arranged in the plurality of openings, and wherein there is further disposed a transition light-emitting layer in the transition area;
a metal barrier layer, arranged in the transition area and on the pixel defining layer;
an inorganic barrier layer, arranged on the metal barrier layer; and
an encapsulation layer, arranged on the plurality of light-emitting elements, the pixel defining layer, and the inorganic barrier layer.

16. The display device as recited in claim 15, wherein the metal barrier layer further comprises a metal barrier extension, wherein at a position of the transition area adjacent to the light-transmitting area, the metal barrier extension is configured to cover respective sides of the pixel driving layer and the pixel defining layer.

17. The display device as recited in claim 16, wherein the inorganic barrier layer further comprises an inorganic barrier extension, which is disposed to cover the metal barrier extension; wherein the encapsulation layer further covers the inorganic barrier extension.

18. The display device as recited in claim 15, wherein an orthographic projection of the metal barrier layer on the substrate lies within a range of an orthographic projection of the inorganic barrier layer on the substrate, and wherein the inorganic barrier layer has a width that is greater than a width of the metal barrier layer;
wherein the transition light-emitting layer comprises a first light-emitting layer and a second light-emitting layer; wherein the inorganic barrier layer is configured to separate the first light-emitting layer from the second light-emitting layer;
wherein the first light-emitting layer is arranged on the pixel defining layer, and the second light-emitting layer is arranged on the inorganic barrier layer and extends to the inorganic barrier extension.

19. The display device as recited in claim 18, wherein a side of the inorganic barrier layer facing away from the light-transmitting area is wider than the metal barrier layer;
wherein an orthographic projection of the first light-emitting layer on the substrate partially overlaps an orthographic projection of the second light-emitting layer on the substrate.

20. The display device as recited in claim 15, wherein the substrate is a flexible substrate and comprises a first organic layer, a barrier layer, and a second organic layer; wherein the first organic layer and the barrier layer each extend from the transition area to the light-transmitting area;
wherein the second organic layer is disposed in the transition area.
